(19) United States
(12) Patent Application Publication
(10) Pub. No.: US 2019/0131314 A1
(43) Pub. Date: May 2, 2019

(54) VeSFlash Non-Volatile Memory

(71) Applicant: The Charles Stark Draper Laboratory, Inc., Cambridge, MA (US)

(72) Inventors: Jordan Chesin, Cambridge, MA (US); Winston Chern, Cambridge, MA (US); Richard H. Morrison, JR., Taunton, MA (US); Amy Duwel, Cambridge, MA (US); John M. Muza, Venetia, PA (US)

(21) Appl. No.: 16/177,276

(22) Filed: Oct. 31, 2018

Related U.S. Application Data
(60) Provisional application No. 62/580,401, filed on Nov. 1, 2017.

(51) Int. Cl. H01L 27/11558; H01L 27/11551

(52) U.S. Cl. CPC H01L 27/11558; H01L 27/11551

(57) ABSTRACT

A non-volatile memory device (VeSFlash) comprises a vertical slit field effect transistor (VeSFET) device comprising a semiconductor portion defining a source end, a drain end, and a slit portion between the source end and the drain end. The VeSFlash non-volatile memory device further comprises at least one floating gate coupled to a side of the slit portion through an insulating layer. The floating gate is coupled to a contact through a second insulating layer. The VeSFlash non-volatile memory device further comprises either another floating gate or an independent control gate. In the case of comprising a control gate coupled to a side wall of the slit portion through a third insulating layer, and the control gate further coupled to a second contact, it is configured to accommodate an access signal, and the floating gate configured to accommodate a data signal. In the case of comprising a second floating gate coupled to a side of the slit portion through a third insulating layer, further coupled to a second contact through a fourth insulating layer, the floating gates accommodate both the access and data signals.

### RELATED APPLICATIONS

This application clams the benefit of U.S. Provisional Application No. 62/580,401, filed on Nov. 1, 2017. This application is related to U.S. Provisional Application No. 62/466,673, filed on Mar. 3, 2017, and to U.S. Provisional Application No. 62/580,379, filed on Nov. 1, 2017. The entire teachings of the above applications are incorporated herein by reference.

### BACKGROUND

Integration of memory on-chip is a desirable configuration for computing, since many applications currently spend over 80% of their power on accessing memory off-chip. Typical memory fabrication process flows are separate from complementary metal-oxide-semiconductor (CMOS) process flow used for logic. While on-chip memory can be implemented with SRAM using the same process flow as is used to implement the logic, doing so is inefficient because the memory requires 6 transistors per bit of memory.

### SUMMARY

VeSFlash non-volatile memory may fit into a Vertical Slit Field Effect Transistor (VeSFET) process flow with the same footprint as an individual transistor, allowing for integration of memory and logic with only one additional major step in the processing. This same design can also be used with materials that allow for low-temperature processing.

The dual-gate design of the VeSFET may provide the option for a tri-state memory device to increase memory density. The unique lateral layout of the VeSFlash device can also be leveraged to separate the control gate from the floating gate for potentially faster read times.

In one aspect, the invention may be a semiconductor device that comprises a vertically-oriented semiconductor portion defining a source end, a drain end, and a connecting portion between the source end and the drain end. The semiconductor device may further comprise at least one floating gate coupled to a first side of the connecting portion through a first insulating layer. The floating gate may be coupled to a contact through a second insulating layer. The semiconductor device may further comprise at least one control gate coupled to a second side of the connecting portion, opposite the first side of the connecting portion, through a third insulating layer.

The semiconductor device may further comprise a source contact coupled to the source end of the semiconductor portion, and situated above a heavily doped region within the source end of the semiconductor portion. The semiconductor device may further comprise a drain contact coupled to the drain end of the semiconductor portion and situated a heavily doped region within the drain end of the semiconductor portion.

The source contact and the drain contact may be disposed over a heavily doped region of the semiconductor portion, thereby forming a short-channel semiconductor device.

The semiconductor device may further comprise a binary state reader configured to (i) apply a read voltage to the control gate, (ii) sample a current flowing through the connecting portion, and (iii) produce a decision of one of a first binary state and a second binary state based on the sampled current flowing through the connecting portion.

The at least one floating gate may be configured to facilitate a first path of charge carriers to the at least one floating gate and a second path of charge carriers to the at least one floating gate. The first path of charge carriers may comprise direct tunneling through the first insulating layer, and the second path of charge carriers comprises direct tunneling through the second insulating layer. The first path facilitates a write operation by supplying a charge to the at least one floating gate, and the second path facilitates an erase operation by removing a stored charge from the floating gate.

In another aspect, the invention may be a semiconductor memory device that comprises a vertical slit field effect transistor (VeSFET) device. The VeSFET may comprise (i) a semiconductor portion defining a source end, a drain end, and a slit portion between the source end and the drain end, (ii) a control gate coupled to a first side wall of the slit portion through a first insulating layer, the control gate further coupled to a first contact, and (iii) a floating gate coupled to a second side of the slit portion through a second insulating layer, the floating gate coupled to a second contact through a third insulating layer. The control gate may be configured to accommodate a data access signal, and the floating gate may be configured to accommodate a data signal.

The semiconductor memory device may further comprise a source contact coupled to the source end of the semiconductor portion, and situated above a heavily doped region within the source end of the semiconductor portion. The semiconductor memory device may further comprise a drain contact coupled to the drain end of the semiconductor portion and situated a heavily doped region within the drain end of the semiconductor portion.

The source contact and the drain contact may be disposed over a heavily doped region of the semiconductor portion, thereby forming a short-channel semiconductor device.

The semiconductor memory device may further comprise a binary state reader configured to (i) apply a read voltage to the control gate, (ii) sample a current flowing through the connecting portion, and (iii) produce a decision of one of a first binary state and a second binary state based on the sampled current flowing through the connecting portion.

The at least one floating gate may be configured to facilitate a first path of charge carriers to the at least one floating gate and a second path of charge carriers to the at least one floating gate. The first path of charge carriers may comprise direct tunneling through the first insulating layer, and the second path of charge carriers may comprise direct tunneling through the second insulating layer.

The first path may facilitate a write operation by supplying a charge to the at least one floating gate, and the second path facilitates an erase operation by removing a stored charge from the floating gate.

In another aspect, the invention may be a tri-state semiconductor device comprising a vertical slit field effect transistor (VeSFET) device. The VeSFET device may comprise a semiconductor portion defining a source end, a drain end, and a slit portion between the source end and the drain end. The VeSFET device may further comprise a first floating gate coupled to a first side wall of the slit portion through a first insulating layer. The first floating gate may be coupled to a first contact through a second insulating layer. The VeSFET device may further comprise a second floating gate coupled to a second side of the slit portion through a third insulating layer. The floating gate may be coupled to a second contact through a third insulating layer.

The tri-state semiconductor device may further comprise a source contact coupled to the source end of the semiconductor portion, and situated above a heavily doped region within the source end of the semiconductor portion. The tri-state semiconductor device may further comprise a drain contact coupled to the drain end of the semiconductor portion and situated a heavily doped region within the drain end of the semiconductor portion. The source contact and the drain contact may be disposed over a heavily doped region of the semiconductor portion, thereby forming a short-channel semiconductor device.

The semiconductor device may further comprise a binary state reader configured to (i) apply a read voltage to the control gate, (ii) sample a current flowing through the connecting portion, and (iii) produce a decision of one of a first binary state and a second binary state based on the sampled current flowing through the connecting portion.

The at least one floating gate may be configured to facilitate a first path of charge carriers to the at least one floating gate and a second path of charge carriers to the at least one floating gate. The first path of charge carriers may comprise direct tunneling through the first insulating layer, and the second path of charge carriers comprises direct tunneling through the second insulating layer.

### BRIEF DESCRIPTION OF THE DRAWINGS

The patent or application file contains at least one drawing executed in color. Copies of this patent or patent application publication with color drawings will be provided by the Office upon request and payment of the necessary fee.

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1 illustrates basic concepts concerning the VeSFET and the VeSFlash devices constructed according to the invention.

FIG. 2 illustrates functionality of the VeSFET for a charged floating gate and an un-charged floating gate, according to the invention.

FIG. 3 shows a short-channel version of the VeSFlash according to the invention.

FIG. 4 shows tri-state operation of a VeSFlash device, according to the invention.

FIGS. 5-8 illustrate an example embodiment of a VeSFlash process flow, according to the invention.

FIG. 9 illustrates a memory density range of an example VeSFlash device according to the invention.

FIG. 10 shows example tunneling currents into VeSFlash floating gate for several material sets.

### DETAILED DESCRIPTION

A description of example embodiments follows.

The teachings of all patents, published applications and references cited herein are incorporated by reference in their entirety.

The Vertical Slit Field Effect Transistor (VeSFET) provides an alternative path to traditional CMOS process-flows, with transistors defined laterally rather than into the silicon substrate as CMOS typically is, allowing for full control over device dimensions and an ideal platform for three-dimensional (3D) stacking of chips. The VeSFlash design provides a new option for on-chip memory integration. VeSFlash non-volatile memory fits into a VeSFET process flow with the same footprint as an individual transistor (i.e., one transistor/bit), allowing for integration of memory and logic with only one additional major step in the processing. This same design for the VeSFlash can also be used with materials that allow for low temperature processing, opening a path to stacking non-volatile memory with back end processing. In either scheme (high-temperature or low-temperature processing), the dual-gate design also provides the option for a tri-state memory device, potentially doubling the memory density. The unique lateral layout of the VeSFlash device can also be leveraged to separate the control gate from the floating gate for potentially faster read times.

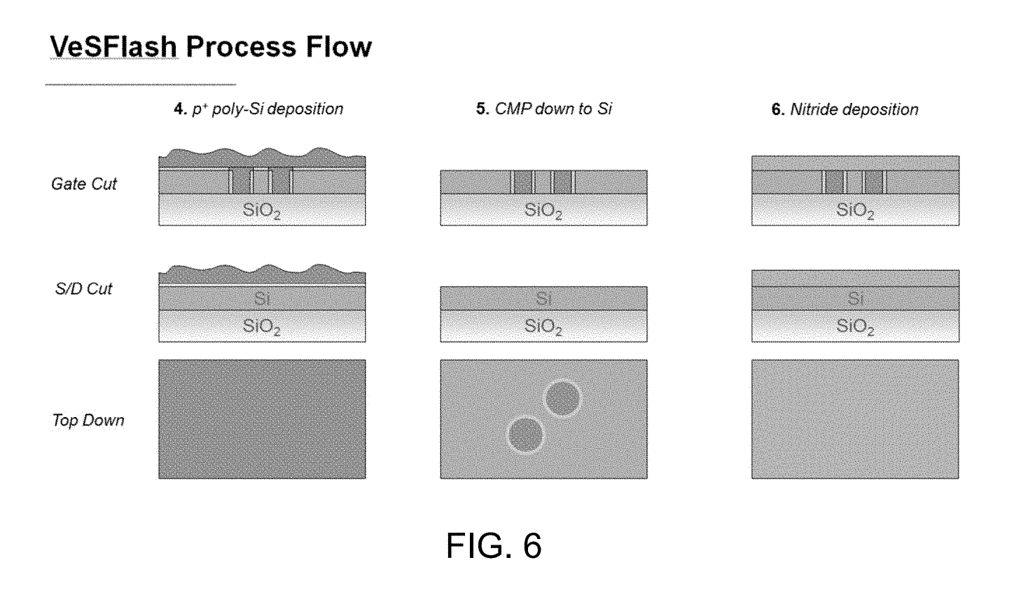

The VeSFlash device works by storing a charge in a floating gate, just as general flash memory works. Rather than using a polysilicon control gate (CG) above the polysilicon floating gate (FG) separated by an inter-poly dielectric, however, the VeSFlash design allows for the control gate to be fabricated as a typical VeSFET gate would be, on the other side of the channel. The VeSFET-basis for the device has two-gates and the VeSFlash device is modified so that one of these gates is the floating gate, shown in FIG. 6.

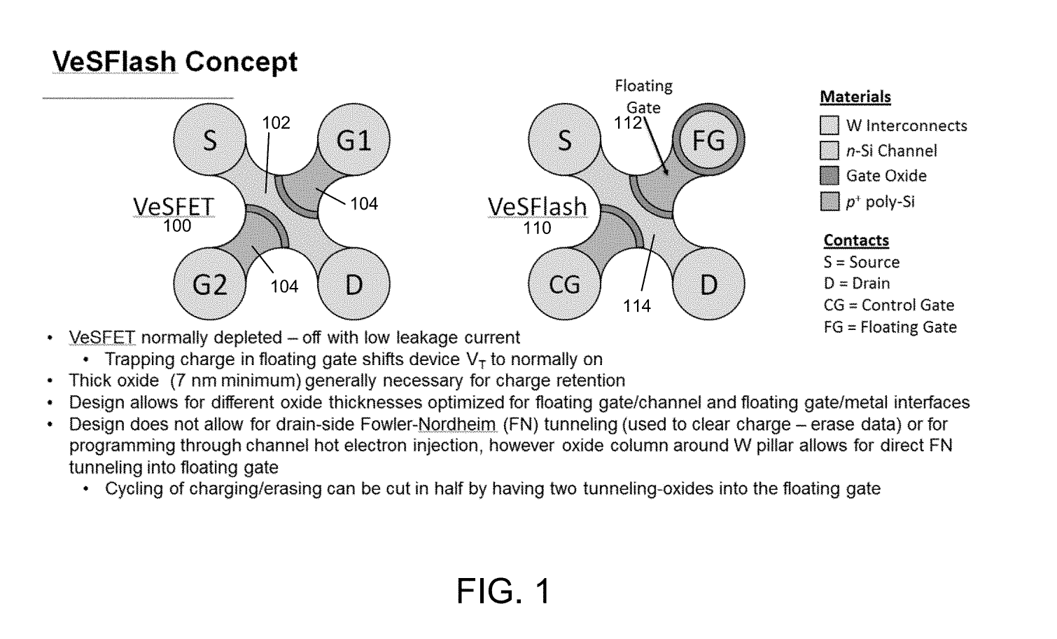

The example structures shown in FIG. 1 illustrate basic concepts concerning the VeSFET and the VeSFlash devices. The VeSFET 100 itself is a majority carrier, junction-less device. The VeSFET channel 102 is doped to a lower level than the polysilicon gates 104, which is the opposite dopant type (e.g., an n-type channel with p-type polysilicon gates). The work-function difference between the polysilicon gate 104 and the channel 102 depletes carriers in the channel region such that with no bias on the gate, only very low leakage current is allowed through the channel. As the gates are biased, the depletion region in the channel shrinks until a majority carrier current path is opened. The VeSFET design has demonstrated high on-off current ratios and very low leakage currents (less than 10⁻¹³ A). By properly choosing the size and doping levels of the VeSFET, the device can also facilitate logical gate functionality. For example, in an OR logic configuration, the transistor can be turned on by biasing either gate.

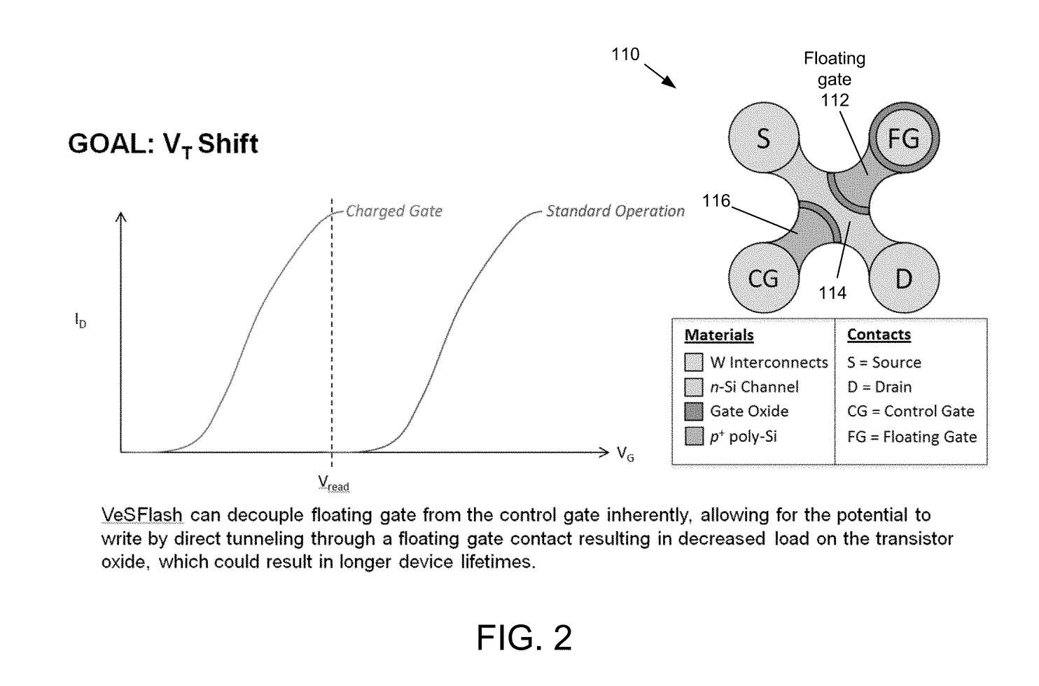

The VeSFlash device 110 is based on a VeSFET sized and doped such that it is an OR logic gate, thus the charge stored on the floating gate 112 is sufficient to allow current flow through the channel 114 (see, e.g., FIG. 2). The result of stored charge on the floating gate 112 is to shift the threshold voltage, such that at some read-voltage (V_{read}) on the control gate 116, a VeSFlash with stored charge on the floating gate 112 will allow current flow through the channel, while VeSFlash will not allow current flow in the case of an un-charged floating gate. The VeSFlash device may thus provide storage capability for a binary state, i.e., a charged floating gate represents a first binary state, and an un-charged floating gate represents a second binary state. Channel current flow at V_{read} may indicate charge stored on the floating gate, and thus a “read” of the first binary state. An absence of current flow at V_{read} may indicate no charge stored on the floating gate, and thus a “read” of the second binary state.

The unique VeSFET-based layout of the VeSFlash device allows for Fowler-Nordheim (FN) tunneling of carriers into the floating gate through either the gate oxide of the channel or the insulating oxide between the metal plug and the floating gate. Dual access to the floating gate means that one path can be assigned for writing (charging up the floating gate) and the other can be assigned to erasing (removing the stored charge from the floating gate). This division halves the cycles that a typical flash device would apply to the tunneling oxide, increasing the device lifetime before material breakdown. Typical flash devices take advantage of asymmetry across the transistor channel using hot-carrier effects and drain-induced tunneling to avoid full FN tunneling through the oxide for every charge/erase, which would require higher voltage across the tunneling oxide.

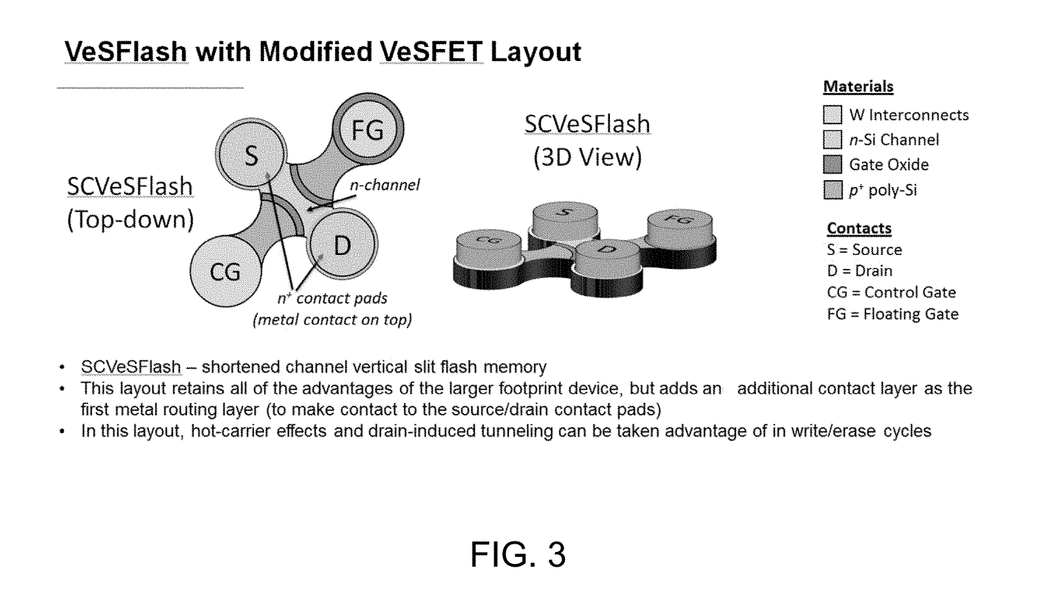

The VeSFlash may be modified from the typical VeSFET layout to achieve the same things by moving in the source and drain contacts to be above a heavily doped region resulting in short-channel VeSFlash (SCVeSFlash). FIG. 3 shows a short-channel version of the VeSFlash device (SCVeSFlash), according to the invention. This SCVeSFlash allows for using less demanding methods of writing (charging the floating gate) and erasing (un-charging the floating gate), such as using hot-carrier effects to write and drain-induced tunneling to erase.

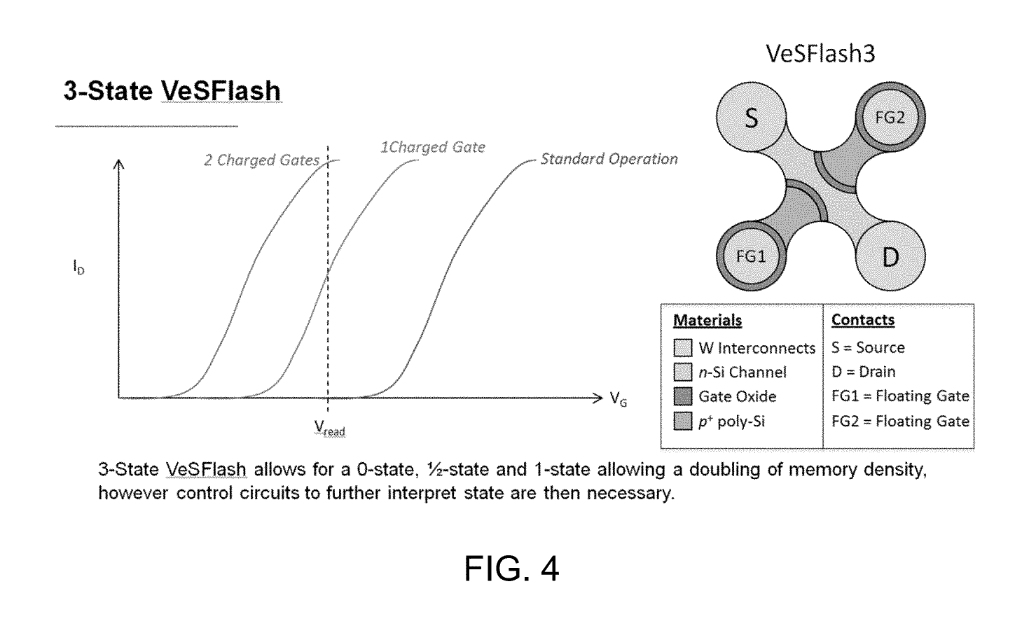

Another modification to the device layout can allow for tri-state VeSFlash (VeSFlash3), which is fabricated such that both gates are floating gates. In this configuration, the underlying VeSFET may be designed such that the device is in the subthreshold regime at V_{read} with trapped charge on only one gate. Thus, the device with two charged floating-gates will be fully turned on and with no charged floating-gates will be fully off, as shown in FIG. 4. The SCVeSFlash concept, described with respect to FIG. 3, may be applied to the VeSFlash3 design as well.

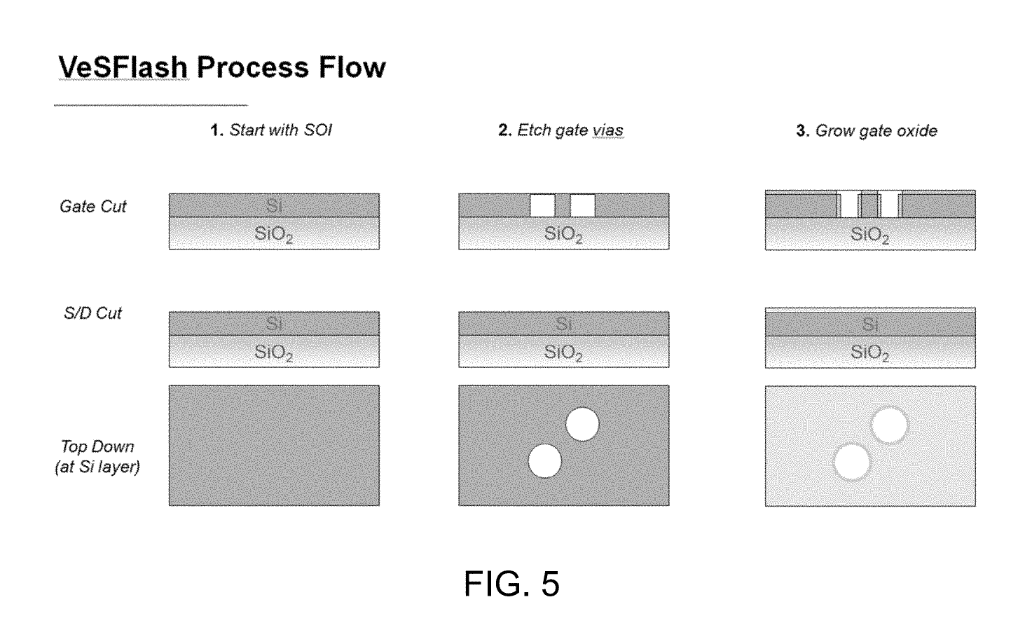

The VeSFlash process flow closely follows the typical VeSFET process flow, with only two additional mask levels. An example embodiment of the process flow is summarized in FIGS. 5-8. Although some of the parameters of the process (e.g., layer thickness) may be specified in this example, these parameters are intended to be examples, and are not intended to be limiting.

In an example embodiment, the substrate is a silicon-on-insulator (SOI) wafer. The example process starts by etching vias where the gates will be formed, as shown in step 2 of FIG. 5. Then a thermal SiO₂ is grown on the sidewalls of the etched vias (step 3 of FIG. 5) and filled with chemical vapor deposited (CVD) polysilicon, doped with boron with a concentration greater than 1×10¹⁹ during the p+ poly-Si deposition (step 4 of FIG. 6).

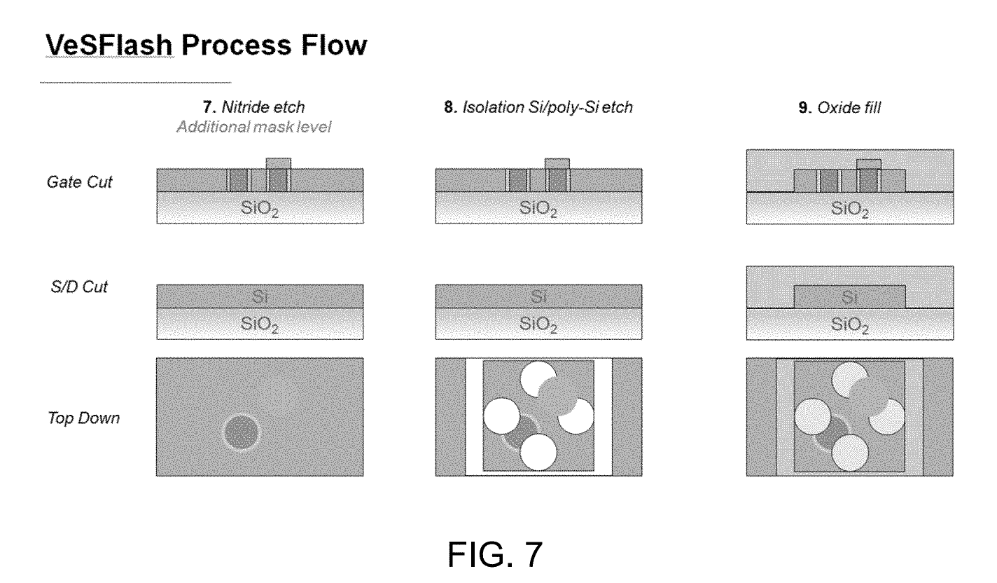

To ensure planarity for further processing, this layer is flattened with chemical-mechanical polishing (CMP) down to the silicon layer (step 5 of FIG. 6). Next, a Si₃N₄ film is deposited by CVD (step 6 of FIG. 6) and then etched such that it is only left over the floating gate as an etch-stop (step 7 of FIG. 7). The devices are isolated with an isolation etch through the silicon (step 8 of FIG. 7) and filled with CVD SiO₂ (step 9 of FIG. 7).

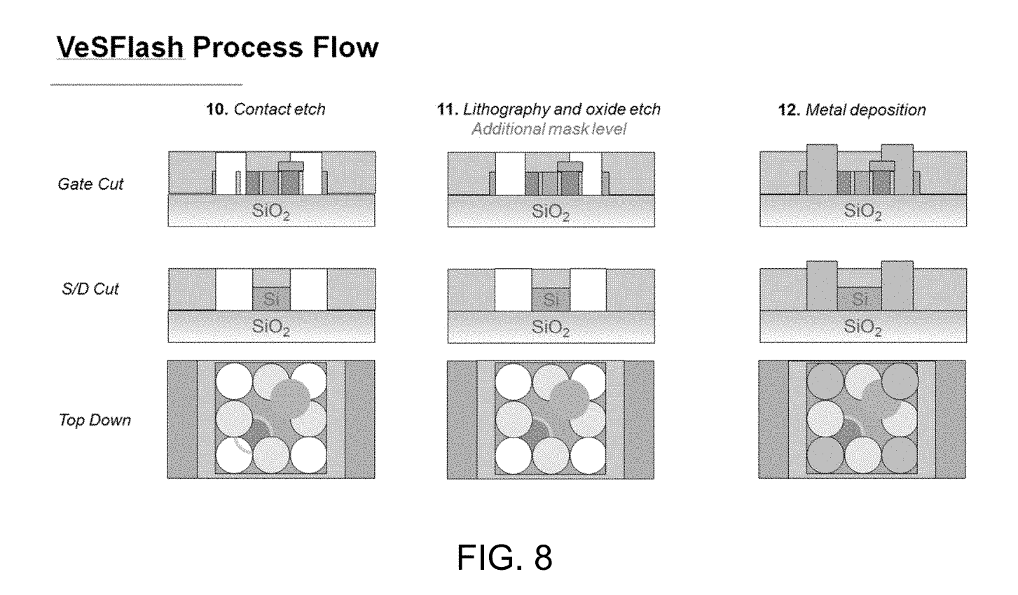

Contact vias are etched for the source, drain and gates (step 10 of FIG. 8). This etch is just an oxide dry etch down to the silicon followed by a silicon dry etch, with the floating gates being protected by the Si₃N₄. To remove any remaining SiO₂ at the control gates, a lithographically-defined wet oxide etch is used to clear the contact holes to the control gate (step 11 of FIG. 8). Finally, metal is deposited into these vias, making direct contact to the polysilicon in the case of the control gate and only interfacing with the SiO₂ of the floating gate.

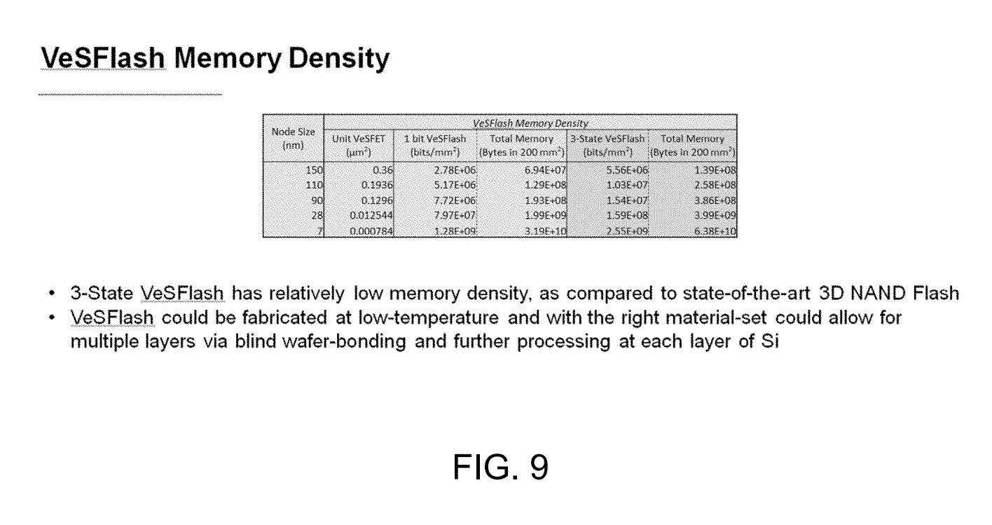

One additional advantage to the VeSFlash design is the possibility for low-temperature processing (≤450° C.), which may open a path to layering the memory layers directly on VeSFET logic to increase the memory density. As an example of the opportunity this provides, a single layer of VeSFlash would have a memory density of 10 MB/mm² at the 28 nm node, as set forth in FIG. 9 (node size is assumed to be equal to the diameter of the circle-basis for the device design). With multiple layers that density could be increased by a factor equal to the number of layers (e.g., 10 layers at the 28 nm node results in a density of 100 MB/mm²) and the low temperature processing will not affect the underlying logic layer.

In an example embodiment, the low temperature processed version of the VeSFlash device may start by SiO₂—SiO₂ bonding an SOI wafer without any alignment. By etching or otherwise removing the handle wafer of the SOI, the resulting stack leaves a layer of pristine crystalline silicon bonded to an already fabricated logic layer. A rough blast mask may then be used to etch down to the initial alignment marks used in the processing of the logic layer, to allow for precise alignment to make contact between the layers. After this step, the VeSFlash may be fabricated following the same process flow as the high-temperature processed VeSFlash, only replacing the tunneling thermally grown oxide (refer to step 3 in FIG. 5) with atomic-layer deposition of dielectrics such as hafnium oxide and the polysilicon gate deposition (refer to step 4 in FIG. 6) is replaced with a metallic compound such as TiN. A low temperature deposition of an etch stop may be used to replace the Si₃N₄ etch stop (see step 6 on FIG. 6).

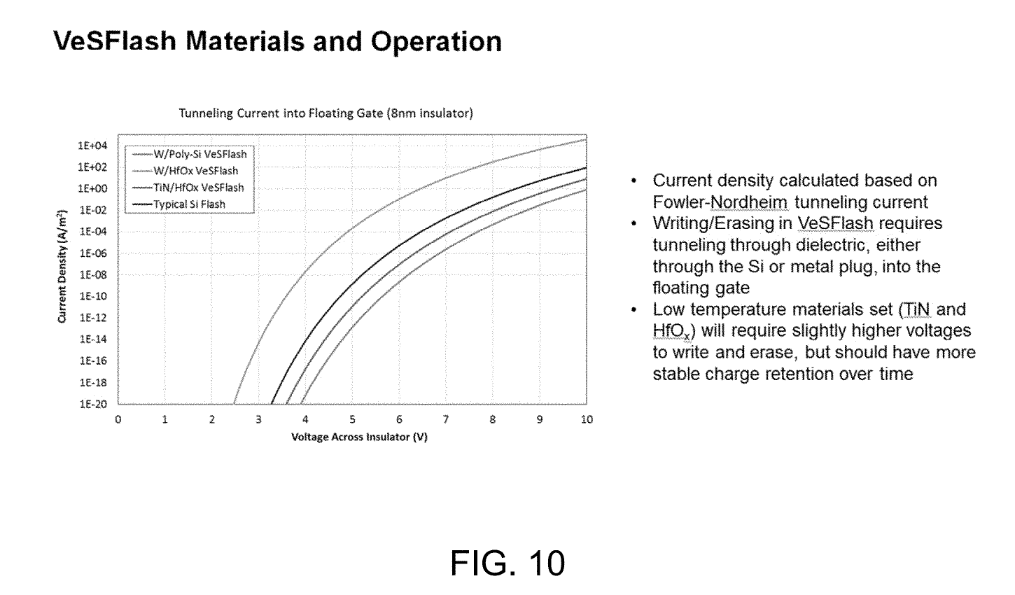

The performance of these materials in the VeSFlash device may be similar to a traditional material set, with the example of tunneling through hafnium oxide from TiN plugs requiring 0.3 V less bias to reach the same tunneling current density (see, e.g., FIG. 10). One concern with low temperature materials such as hafnium oxide is the higher electron affinity than SiO₂ leading to worse charge retention. The VeSFlash design avoids this issue by also using a higher work-function metallic compound, such as TiN for the gate. The information of FIG. 10 demonstrates the feasibility for the low temperature fabrication of the devices described herein.

While example embodiments have been particularly shown and described, it will be understood by those skilled in the art that various changes in form and details may be made therein without departing from the scope of the embodiments encompassed by the appended claims.

What is claimed is:

1. A semiconductor device comprising:
a vertically-oriented semiconductor portion defining a source end, a drain end, and a connecting portion between the source end and the drain end;
at least one floating gate coupled to a first side of the connecting portion through a first insulating layer, the floating gate coupled to a contact through a second insulating layer; and
at least one control gate coupled to a second side of the connecting portion, opposite the first side of the connecting portion, through a third insulating layer.

2. The semiconductor device of claim 1, further comprising:
a source contact coupled to the source end of the semiconductor portion, and situated above a heavily doped region within the source end of the semiconductor portion; and
a drain contact coupled to the drain end of the semiconductor portion and situated a heavily doped region within the drain end of the semiconductor portion.

3. The semiconductor device of claim 2, wherein the source contact and the drain contact are disposed over a heavily doped region of the semiconductor portion, thereby forming a short-channel semiconductor device.

4. The semiconductor device of claim 1, further comprising a binary state reader configured to (i) apply a read voltage to the control gate, (ii) sample a current flowing through the connecting portion, and (iii) produce a decision of one of a first binary state and a second binary state based on the sampled current flowing through the connecting portion.

5. The semiconductor device of claim 1, wherein the at least one floating gate is configured to facilitate a first path of charge carriers to the at least one floating gate and a second path of charge carriers to the at least one floating gate.

6. The semiconductor device of claim 5, wherein the first path of charge carriers comprises direct tunneling through the first insulating layer, and the second path of charge carriers comprises direct tunneling through the second insulating layer.

7. The semiconductor device according to claim 5, wherein the first path facilitates a write operation by supplying a charge to the at least one floating gate, and the second path facilitates an erase operation by removing a stored charge from the floating gate.

8. A semiconductor memory device comprising:
a vertical slit field effect transistor (VeSFET) device comprising:
a semiconductor portion defining a source end, a drain end, and a slit portion between the source end and the drain end;
a control gate coupled to a first side wall of the slit portion through a first insulating layer, the control gate further coupled to a first contact; and
a floating gate coupled to a second side of the slit portion through a second insulating layer, the floating gate coupled to a second contact through a third insulating layer;
the control gate configured to accommodate a data access signal, and the floating gate configured to accommodate a data signal.

9. The semiconductor memory device of claim 8, further comprising:
a source contact coupled to the source end of the semiconductor portion, and situated above a heavily doped region within the source end of the semiconductor portion; and
a drain contact coupled to the drain end of the semiconductor portion and situated a heavily doped region within the drain end of the semiconductor portion.

10. The semiconductor memory device of claim 9, wherein the source contact and the drain contact are disposed over a heavily doped region of the semiconductor portion, thereby forming a short-channel semiconductor device.

11. The semiconductor memory device of claim 8, further comprising a binary state reader configured to (i) apply a read voltage to the control gate, (ii) sample a current flowing through the connecting portion, and (iii) produce a decision of one of a first binary state and a second binary state based on the sampled current flowing through the connecting portion.

12. The semiconductor memory device of claim 8, wherein the at least one floating gate is configured to facilitate a first path of charge carriers to the at least one floating gate and a second path of charge carriers to the at least one floating gate.

13. The semiconductor memory device of claim 12, wherein the first path of charge carriers comprises direct tunneling through the first insulating layer, and the second path of charge carriers comprises direct tunneling through the second insulating layer.

14. The semiconductor memory device according to claim 12, wherein the first path facilitates a write operation by supplying a charge to the at least one floating gate, and the second path facilitates an erase operation by removing a stored charge from the floating gate.

15. A tri-state semiconductor device comprising:
a vertical slit field effect transistor (VeSFET) device comprising:
a semiconductor portion defining a source end, a drain end, and a slit portion between the source end and the drain end;
a first floating gate coupled to a first side wall of the slit portion through a first insulating layer, the first floating gate coupled to a first contact through a second insulating layer;
a second floating gate coupled to a second side of the slit portion through a third insulating layer, the floating gate coupled to a second contact through a third insulating layer.

16. The tri-state semiconductor device of claim 15, further comprising:
a source contact coupled to the source end of the semiconductor portion, and situated above a heavily doped region within the source end of the semiconductor portion; and
a drain contact coupled to the drain end of the semiconductor portion and situated a heavily doped region within the drain end of the semiconductor portion.

17. The semiconductor device of claim 16, wherein the source contact and the drain contact are disposed over a heavily doped region of the semiconductor portion, thereby forming a short-channel semiconductor device.

18. The semiconductor device of claim 15, further comprising a binary state reader configured to (i) apply a read voltage to the control gate, (ii) sample a current flowing through the connecting portion, and (iii) produce a decision of one of a first binary state and a second binary state based on the sampled current flowing through the connecting portion.

19. The semiconductor device of claim 15, wherein the at least one floating gate is configured to facilitate a first path of charge carriers to the at least one floating gate and a second path of charge carriers to the at least one floating gate.

20. The semiconductor device of claim 19, wherein the first path of charge carriers comprises direct tunneling through the first insulating layer, and the second path of charge carriers comprises direct tunneling through the second insulating layer.
